(19) United States
(12) Patent Application Publication
(10) Pub. No.: US 2024/0276790 A1
(43) Pub. Date: Aug. 15, 2024

(54) DISPLAY PANEL, METHOD FOR MANUFACTURING THE SAME, AND DISPLAY DEVICE

(71) Applicant: Hubei Yangtze Industrial Innovation Center Of Advanced Display Co., Ltd., Wuhan (CN)

(72) Inventors: Chunhui YANG, Wuhan (CN); Kang YANG, Xiamen (CN)

(73) Assignee: Hubei Yangtze Industrial Innovation Center Of Advanced Display Co., Ltd., Wuhan (CN)

(21) Appl. No.: 18/644,143

(22) Filed: Apr. 24, 2024

(30) Foreign Application Priority Data
Oct. 31, 2023 (CN) 202311440747.4

(51) Int. Cl. H10K 59/122; H10K 59/12; H10K 59/131; H10K 59/40; H10K 102/00

(52) U.S. Cl. CPC H10K 59/122; H10K 59/1201; H10K 59/131; H10K 59/40; H10K 2102/311

(57) ABSTRACT

A display panel, a method for manufacturing the display panel, and a display device. The display panel includes an array substrate, where a display region of the array substrate is surrounded by a border region of the array substrate, and the border region includes an organic-layer-free region; a protruding structure, disposed in the border region and at a side of the organic-layer-free region away from the display region; and a packaging layer, covering the display region and at least a part of the border region, where the packaging layer is disposed at a side of the protruding structure facing the display region. It is less likely that a material of the packaging layer is deposited in the electrical connection region of the border region during manufacture and thereby affects performances of electrical connection in the border region.

The present disclosure claims the priority to Chinese Patent Application No. 202311440747.4, titled “DISPLAY PANEL, METHOD FOR MANUFACTURING THE SAME, AND DISPLAY DEVICE”, filed on Oct. 31, 2023 with the China National Intellectual Property Administration, the content of which is incorporated herein by reference.

### FIELD

The present disclosure relates to the field of displays, and in particular to a display panel, a method for manufacturing the display panel, and a display device.

### BACKGROUND

Display panels are applied to more and more scenarios with development of display technology and are becoming indispensable components of electronic devices. Common types of the display panels include liquid crystal display (LCD), organic light-emitting diode (OLED) display, panel, and the like. The OLED display panels have become a mainstream in the field due to its lightness, small thickness, large viewing angle, and significant reduction in power consumption.

During manufacture, an OLED display panel needs to be packaged through a packaging film or a packaging layer, and a light-emitting material in a display region of the OLED display panel is isolated from ambient vapor and oxygen. In conventional manufacture, the packaging layer of the OLED display panel may extend into an electrical connection region in a border region of the display panel, and thereby affect performances of electrical connections in the border region.

### SUMMARY

A display panel, a method for manufacturing the display panel, and a display device are provided according to embodiments of the present disclosure. A packaging layer of the display panel does not extend into an electrical connection region of a border region of the display panel, and performances of electrical connections in the border region would not be affected.

Following solutions are provided according to the embodiments of the present disclosure.

In one embodiment, a display panel is provided according to embodiments of the present disclosure. The display panel includes: an array substrate, where a display region of the array substrate is surrounded by a border region of the array substrate, and the border region includes an organic-layer-free region; a protruding structure, disposed in the border region and at a side of the organic-layer-free region away from the display region; and a packaging layer, covering the display region and at least a part of the border region, where the packaging layer is disposed at a side of the protruding structure facing the display region.

In an embodiment, the display panel further includes a touch electrode layer disposed at a side of the packaging layer away from the array substrate. The array substrate further includes a metal wiring layer, and the touch electrode layer is electrically connected to the metal wiring layer through a first via.

In an embodiment, the border region includes a first border region and a second border region which are at opposite sides of the display region along a first direction. The first border region includes a bendable region, and the first via is arranged in the first border region. The protruding structure is arranged in the first border region and between the organic-layer-free region and the first via.

In an embodiment, a dimension of the protruding structure along a second direction is greater than a dimension of the display region along the second direction, and the second direction is perpendicular to the first direction.

In an embodiment, the border region includes a third border region and a fourth border region which are at opposite sides of the display region along a second direction, and an anti-cracking groove is arranged in one or both of the third border region and the fourth border region. The protruding structure is arranged in the one or both of the third border region and the fourth border region and at the side of the organic-layer-free region away from the display region.

In an embodiment, a dimension of the protruding structure along the second direction is greater than a dimension of a boundary between the display region and the border region along the second direction.

In an embodiment, the protruding structure extends along a direction parallel with a boundary between the display region and the border region, and the protruding structure includes a continuous protruding strip.

In an embodiment, the protruding structure extends along a direction parallel with a boundary between the display region and the border region. The protruding structure include at least to two rows of protruding units, every two adjacent protruding units in each of the two rows are separated by a gap, and a projection of the two rows of protruding units on the boundary is contiguous.

In an embodiment, the two rows of protruding units includes a first row and a second row sequentially arranged along a direction perpendicular to the direction parallel with the boundary. At least a part of each protruding unit in the second row overlaps with the gap between two corresponding protruding units in the first row when viewed along the direction perpendicular to the direction parallel with the boundary.

In an embodiment, the protruding structure is annular and surrounds the display region.

In an embodiment, the highest point of the array substrate within a first region serves as a target position, the first region includes a part of the border region at a side of the organic-layer-free region away from the display region, and the highest point of a surface of the protruding structure away from the array substrate is not lower than the target position.

In an embodiment, the highest point of the surface of the protruding structure away from the array substrate is higher than the target position.

In an embodiment, the protruding structure is insulating and flexible.

In an embodiment, the protruding structure is an organic layer.

In an embodiment, the display panel includes a layer of thin film transistors, a pixel definition layer, a light-emitting layer, and a support structure, and the protruding structure is fabricated from a same layer as one or both of the pixel definition layer and the support structure.

In one embodiment, a method for manufacturing a display panel is provided according to embodiments of the present disclosure. The method includes: forming an array substrate and a protruding structure, where a display region of the array substrate is surrounded by a border region of the array substrate, the border region includes an organic-layer-free region, the protruding structure is formed in the border region and at a side of the organic-layer-free region away from the display region; disposing a mask on a side of the protruding structure away from the array substrate, where at least the display region is located within a projection of an opening in the mask on the array substrate, and at least a part of a projection of the protruding structure on the array substrate is located within a projection of a non-opening region of the mask on the array substrate; and forming a packaging layer within the opening through the mask.

In an embodiment, a longitudinal centerline of the protruding structure is located at a side of a boundary of the opening of the mask away from the display region when viewed along a direction perpendicular to the display panel.

In an embodiment, a second region of the mask is located between the opening and a third region of the mask, and the mask in the second region is smaller in thickness than the mask in the third region.

In an embodiment, the projection of the protruding structure on the array substrate is located within a projection of the second region on the array substrate.

In an embodiment, the protruding structure is insulating and flexible, and the mask is a steel mask. The highest point of the array substrate within a first region serves as a target position, and the first region includes a part of the border region at the side of the organic-layer-free region away from the display region. The highest point of a surface of the protruding structure away from the array substrate is not lower than the target position.

In one embodiment, a display device is provided according to embodiments of the present disclosure. The display device includes any foregoing display panel.

The above embodiments are advantageous over conventional technology in at least following embodiments.

The display panel, the method for manufacturing the display panel, and the display device including the display panel are provided. The protruding structure is disposed in the border region of the array substrate, and the mask can be supported by the protruding structure during fabrication of the packaging layer. In one embodiment, a material for forming the packaging layer is hold at a side of the protruding structure facing the display region and is prevented from intruding into the side of the protruding structure away from the display region. It is less likely that the material of the packaging layer is deposited in the electrical connection region of the border region and thereby affects performances of electrical connection in the border region.

### BRIEF DESCRIPTION OF THE DRAWINGS

Hereinafter drawings for illustrating embodiments of the present disclosure are provided for clarify embodiments of the present disclosure. The drawings only represent some embodiments of the present disclosure.

FIG. 1 is a schematic diagram showing a mask disposed on a surface of an array substrate.

FIG. 2 is another schematic diagram showing a mask disposed on a surface of an array substrate.

FIG. 3 is a schematic diagram showing collapse of a part of a mask as shown in FIG. 2.

FIG. 4 is a schematic structural diagram of a display panel according to an embodiment of the present disclosure.

FIG. 5 is a schematic structural diagram of a display panel according to another embodiment of the present disclosure.

FIG. 6 is a schematic structural diagram of a display panel when forming a packaging layer according to an embodiment of the present disclosure.

FIG. 7 is a schematic structural diagram of a display panel when forming a packaging layer according to another embodiment of the present disclosure.

FIG. 8 is a schematic structural diagram of a display panel when forming a packaging layer according to another embodiment of the present disclosure.

FIG. 9 is a schematic structural diagram of a cross section of a border region of a display panel according to an embodiment of the present disclosure.

FIG. 10 is a top view of a display panel according to an embodiment of the present disclosure.

FIG. 11 is a schematic structural diagram of a cross section of a display panel according to another embodiment of the present disclosure.

FIG. 12 is a top view of a display panel according to another embodiment of the present disclosure.

FIG. 13 is a top view of a display panel according to another embodiment of the present disclosure.

FIG. 14 is a top view of a display panel according to another embodiment of the present disclosure.

FIG. 15 is a top view of a display panel according to another embodiment of the present disclosure.

FIG. 16 is a top view of a display panel according to another embodiment of the present disclosure.

FIG. 17 is a schematic structural diagram of a display panel when forming a packaging layer according to another embodiment of the present disclosure.

FIGS. 18 to 20 are schematic structural diagrams of relevant parts when manufacturing a display panel according to an embodiment of the present disclosure.

### DETAILED DESCRIPTION

Hereinafter the embodiments of the present disclosure are described in conjunction with the drawings of the embodiments of the present disclosure. Apparently, embodiments described as follows are only some, rather than all, embodiments of the present disclosure. Other embodiments of the present disclosure may fall within the protection scope of the present disclosure.

Various details are set forth in the following description to facilitate a full understanding of the present disclosure. The present disclosure may be implemented in other manners different from those described herein. Those skilled in the art derive other manners without departing from connotation of the present disclosure. Therefore, the present disclosure is not limited to the following embodiments.

The present disclosure would be described in detail in conjunction with schematic diagrams. In following description, a cross-sectional view of a device structure may be partially enlarged not according to a general scale in order to facilitate illustration. The schematic diagrams are only examples and are not intended for limiting a protection scope of the present disclosure. In addition, three spatial dimensions such as a length, a width, and a depth shall be configured in practice.

As described in the background, a packaging layer of an organic light-emitting diode (OLED) display panel may extend into an electrical connection region in a border region of the display panel, and thereby affect performances of electrical connections in the border region.

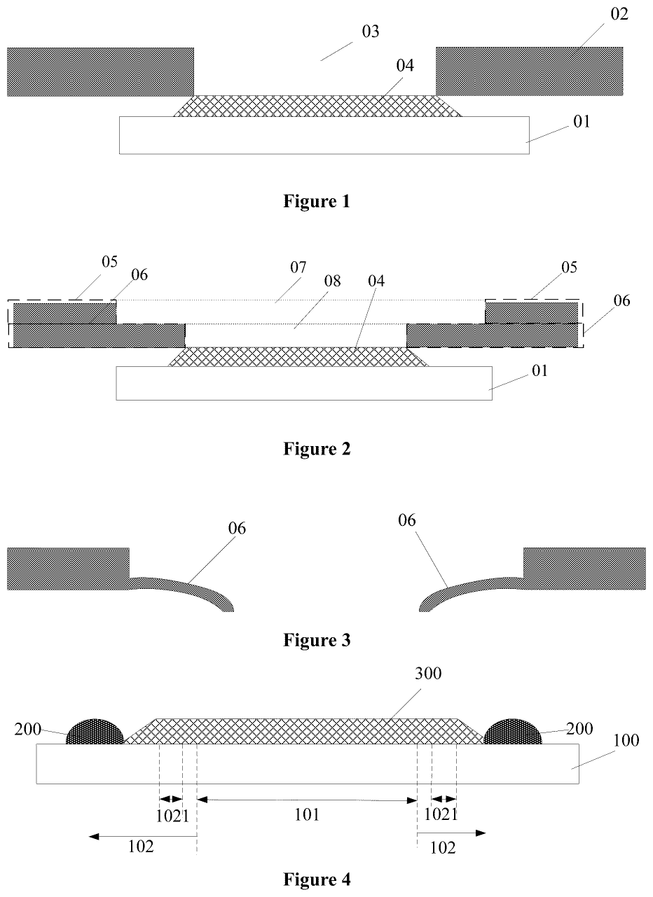

Generally, a conventional OLED display panel may be packaged through an inorganic layer, an organic layer, or a stack of the two. The inorganic layer is taken as an example. As shown in FIG. 1, a mask 02 is disposed on an array substrate 01 of the OLED display panel, the mask 02 is provided with an opening 03, and the opening 03 exposes at least a display region, in which a light-emitting material is located, on the array substrate 01. An inorganic material is formed within the opening 03 of the mask 02 to form an inorganic layer 04.

When forming the inorganic material in the opening of the mask, the inorganic material may be deposited at a position below a non-opening region of the mask. That is, the inorganic layer extends into a border region of the display panel, which renders a subsequent etching process for forming an electrical connection via in such region more difficult. In one embodiment, there may be incomplete etching, which affects performance of electrical connections in such region.

Researches of the inventor reveal that the mask may be fabricated through a semi-etching technique. That is, the mask has a first opening and a second opening which are spatially connected. As shown in FIG. 2, the mask includes a first part 05 and a second part 06 which are vertically stacked. The first opening 07 runs through the first part 05, the second opening 08 runs through the second part 06, and the second opening 08 is located within coverage of the first opening 07. The second opening 08 exposes the display region in which a light-emitting material of the array substrate 01 is located. In one embodiment, when depositing an inorganic layer on the array substrate 01 through the mask, a reduced thickness of the mask adjacent to the second opening 08 is capable to suppress a degree of the inorganic material intruding into a space beneath a non-opening region of the mask.

When suppressing the degree of the inorganic material intruding into the space beneath the non-opening region of the mask, the smaller the thickness of the second part is, the smaller area the inorganic material extends below the non-opening region of the mask by. In a case that the thickness of the second part is too small, a mechanical strength of the second part 06 of the mask would be such inadequate that the second part 06 collapses, as shown in FIG. 3. In such case, normal morphology is hard to maintain.

Researches of the inventor further reveals that a cause of the inorganic material extends below the non-opening region of the mask when being formed in the opening of the mask is as follows. A terrain level on an upper surface of the fabricated array is subject to variations, which results in a gap between the mask and the array substrate when they contact. That is, a surface of the array substrate facing the mask, which is called an N face, and a surface of the mask facing the array substrate, which is called an M-plane, are separated by a gap. Thus, the inorganic material would intrude below the non-opening region of the mask via the gap when being deposited.

A display panel is provided according to an embodiment of the present disclosure. As shown in FIG. 4, the display panel may include an array substrate 100, a protruding structure 200, and a packaging layer 300.

A display region 101 of the array substrate 100 is surrounded by a border region 102 of the array substrate 100, and the border region 102 includes an organic-layer-free region 1021.

The protruding structure 200 is disposed in the border region 102 and at a side of the organic-layer-free region 1021 away from the display region 101.

The packaging layer 300 covers the display region 101 and at least a part of the border region 102, and the packaging layer 300 is disposed at a side of the protruding structure 200 facing the display region 101.

The organic-layer-free region refers to a sub-region of the border region, and in such sub-region, no organic layer has been formed in a space over the array substrate along a direction perpendicular to a plane in which the array substrate is located. The organic-layer-free region is configured to prevent ambient water and oxygen from entering the display region via the organic layer and affecting a display effect of the display panel.

Reference is made to FIG. 5. In an embodiment, the packaging layer 300 includes a first inorganic layer 310, an organic layer 320, and a second inorganic layer 330, which are sequentially stacked. In an embodiment, an area of each of the first inorganic layer 310 and the second inorganic layer 330 is greater than that of the organic layer 320. The first inorganic layer 310 covers the display region 101 and at least a part of the border region 102, the organic layer 320 covers at least the display region 101, and the second inorganic layer 330 covers the display region 101 and at least a part of the border region 102.

Reference is made to FIGS. 4 and 5. In an embodiment, the packaging layer 300 extends horizontally to cover the organic-layer-free region 1021. The present disclosure is not limited thereto depending on an actual situation.

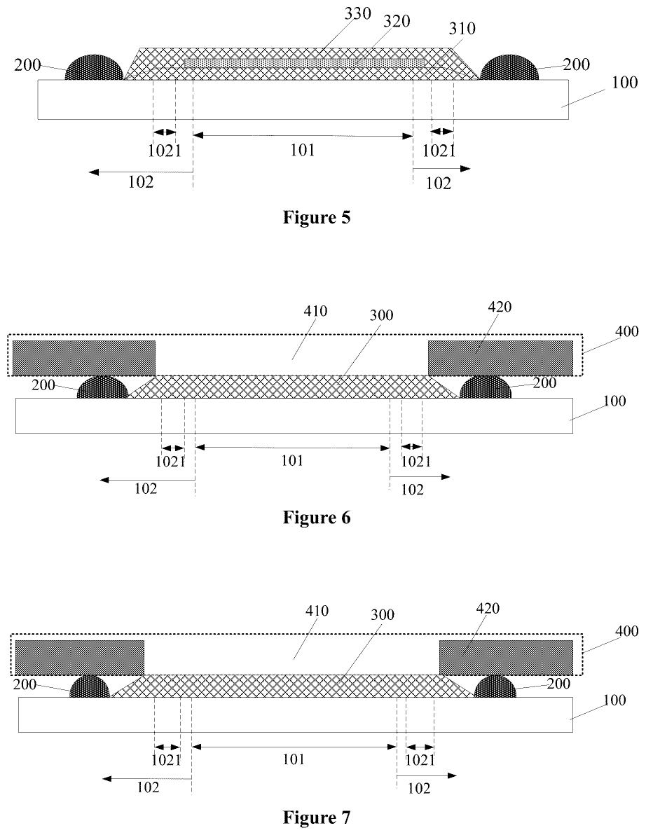

In the foregoing display panel, the protruding structure is disposed in the border region of the array substrate. In one embodiment, the mask 400 may be supported by the protruding structure 200 during fabrication of the packaging layer 300, as shown in FIG. 6. A material for forming the packaging layer 300 is hold at a side of the protruding structure 200 facing the display region 101 and is prevented from intruding into the side of the protruding structure 200 away from the display region 101. It is less likely that the material of the packaging layer 300 is deposited in the electrical connection region of the border region 102 and thereby affects performances of electrical connection in the border region 102.

Herein a cross-sectional view of the protruding structure may be semi-circular (e.g., as shown in FIG. 7), semi-elliptical (e.g., as shown in FIG. 6), rectangular, or of another shape. A specific shape is not limited herein and may depend on an actual situation. Hereinafter it is taken as an example that the cross-sectional view is semi-elliptical for illustrating the display panel.

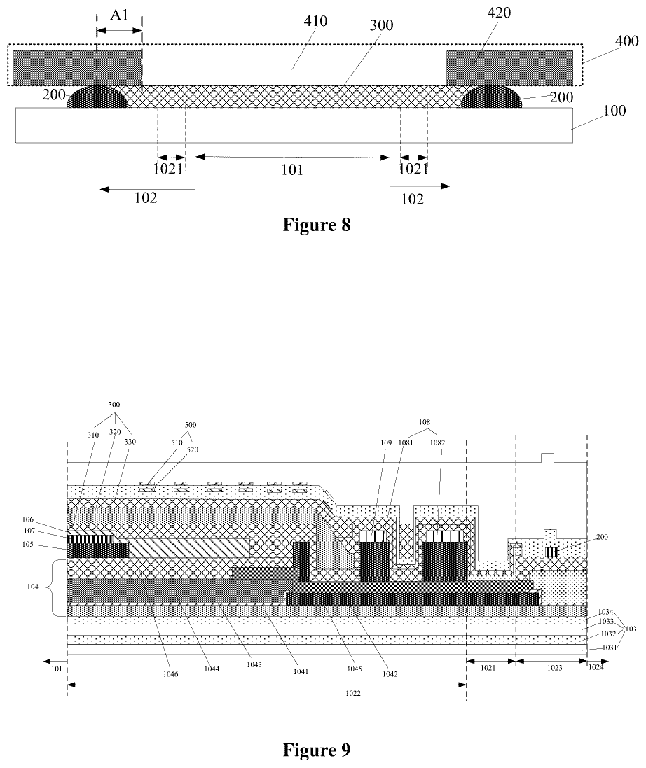

Reference is made to FIG. 8. In an embodiment, the cross-sectional view of the protruding structure 200 is semi-elliptical, and the material for forming the packaging layer 300 may still intrude below a non-opening region 420 of the mask 400 when being deposited, e.g., intrudes into the A1 region as shown in FIG. 8. The protruding structure 200 on the array substrate 100 is capable to support the mask 400 when forming the packaging layer 300, and an area by which the packaging layer 300 extends below the non-opening region 420 may be adjusted based on a location at the protruding structure 200 is disposed. That is, a boundary of the packaging layer 300 in the border region 102 may be adjusted in position. In one embodiment, fabrication of the packaging layer 300 can be prevented from affecting the performances of the electrical connections in the border region 102 of the display panel.

Reference is made to FIG. 9. In an embodiment, a first sub-border region 1022 of the array substrate is located between the display region 101 and the organic-layer-free region 1021, a second sub-border region 1023 and a third sub-border region 1024 of the array substrate are sequentially located at a side of the organic-layer-free region 1021 away from the display region 101. The protruding structure is located in the second sub-border region 1023.

Reference is further made to FIG. 9. In an embodiment, the array substrate includes a first substrate 103, a control circuit layer 104 disposed at a side of the first substrate 103, a pixel definition layer 105 disposed at a side of the control circuit layer 104 away from the first substrate 103, a cathode layer 106 disposed at a side of the pixel definition layer 105 away from the control circuit layer 104, and a common electrode 107 disposed between the cathode layer 106 and the pixel definition layer 105.

Reference is further made to FIG. 9. In an embodiment, in the border region 102, the control circuit layer 104 includes a first insulation layer 1041, a first signal line layer 1042, a passivation layer 1043, a circuit component layer 1044, a second signal line layer 1045, and a planarization layer 1046.

The first insulation layer 1041 is disposed at a surface of the first substrate 103.

The first signal line layer 1042 is disposed at a side of the first insulation layer 1041 away from the surface of the first substrate 103.

The passivation layer 1043 and the circuit component layer 1044 cover the first insulation layer 1041 and at least a part of the first signal line layer 1042. The passivation layer 1043 and the circuit component layer 1044 expose another part of the first signal line layer 1042.

The second signal line layer 1045 is disposed at a side of the circuit component layer 1044 away from the first signal line layer 1042. One or more signal lines in the second signal line layer 1045 are electrically connected to one or more signal lines in the first signal line layer 1042.

The planarization layer 1046 is disposed at a side of the circuit component layer 1044 away from the first substrate 103.

In an embodiment, the array substrate further includes a blocking structure 108 disposed at a side of the second signal line layer 1045 away from the first signal line layer 1042. The blocking structure 108 is configured to block a material of the organic layer 320 in the packaging layer when forming the organic layer 320. In one embodiment, the organic layer 320 in the packaging layer is prevented from intruding into the organic-layer-free region 1021 and affecting an isolation effect against water and oxygen.

In an embodiment, the blocking structure includes a first blocking wall 1081 and a second blocking wall 1082. The second blocking wall 1082 is disposed at a side of the first blocking wall 1081 away from the display region 101, to provide secondary blocking on the material of the organic layer. Hence, a blocking effect of the blocking structure is improved.

In an embodiment, the array substrate further includes a support column 109 disposed on a surface of the blocking structure. The present disclosure is not limited thereto depending on an actual situation.

In an embodiment, the first substrate 103 includes a first thin film 1031, a first buffer layer 1032 disposed on a surface of the first thin film 1031, a second thin film 1033 disposed at a side of the first buffer layer 1032 away from the first thin film 1031, and a second buffer layer 1034 disposed at a side of the second thin film 1033 away from the first buffer layer 1032. In an embodiment, both the first thin film and the second thin film are polyimide films, i.e., PI films. The present disclosure is not limited thereto depending on an actual situation.

In an embodiment, the display panel is a touch-control display panel. Reference is made to FIG. 9. The display panel may further include a touch electrode layer 500, which is disposed at a side of the packaging layer 300 away from the array substrate. In an embodiment, the array substrate further includes a metal wiring layer, and the touch electrode layer is electrically connected to the metal wiring layer through a first via. Along a direction parallel to the array substrate, the first via is disposed at a side of the protruding structure 200 away from the display region 101. That is, the first via may be located in the third sub-border region 1024 as shown in FIG. 9. In one embodiment, the packaging layer 300 is prevented from affecting performances of the electrical connections of the first via.

Reference is further made to FIG. 9. In an embodiment, the touch electrode layer 500 includes a first touch electrode layer 510 and a second touch electrode layer 520. An insulation layer is disposed between the first touch electrode layer 510 and the second touch electrode layer 520. In one embodiment, variation of capacitance between the first touch electrode layer 510 and the second touch electrode layer 520 can be detected to achieve a touch-control function.

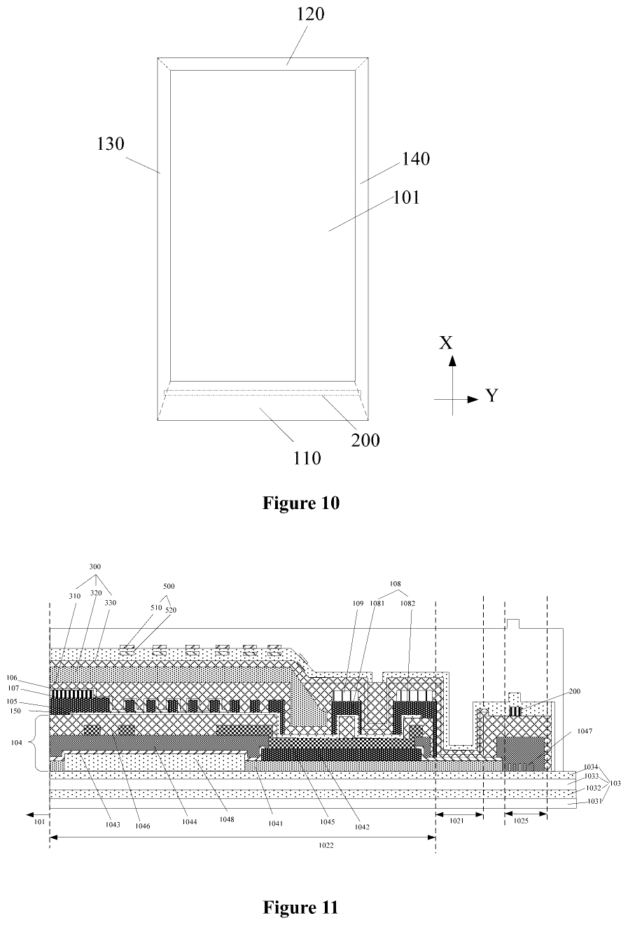

Reference is made to FIG. 10. In an embodiment, the border region includes a first border region 110 and a second border region 120, which are located at opposite sides of the display region along a first direction X. The first border region 110 includes a bendable region. The first border region 110 may be a lower border region of the display panel.

In an embodiment, the first via is located in the first border region, i.e., in the lower border region of the display panel. In an embodiment, the protruding structure is located in the first border region and between the organic-layer-free region and the first via. As shown in FIG. 9, the second sub-border region 1023, in which the protruding structure is located, is located between the organic-layer-free region 1021 and the third sub-border region 1024, in which the first via is located. In one embodiment, the material for forming the packaging layer is blocked by the protruding structure when being deposited. That is, it is prevented that the material is deposited at a region for forming the first via when fabricating the packaging layer. Accordingly, it is prevented that the material affects electrical connection of first via and thereby affects performances of electrical connections in the border region of the display panel.

Reference is further made to FIG. 10. In an embodiment, a dimension of the protruding structure 200 along a second direction Y is greater than a dimension of the display region 101 along the second direction Y. That is, the protruding structure 200 is longer than a boundary between the display region 101 and the border region along the second direction Y. In one embodiment, the material for forming the packaging layer can be effectively blocked by the protruding structure when fabricating the packaging layer which covers the display region. That is, it is prevented that the material is deposited at a region for forming the first via when fabricating the packaging layer. Accordingly, it is prevented that the material affects electrical connection of first via and thereby affects performances of electrical connections in the border region of the display panel.

In the foregoing embodiment(s), it is taken as an example that the protruding structure is disposed in the first border region of the display panel, and FIG. 9 shows a structure of a lower border region of the display panel. In another embodiment, the protruding structure may be disposed in a left border region and/or a right border region of the display panel.

Reference is made to FIG. 10. In an embodiment, the border region of the display panel further includes a third border region 130 and a fourth border region 140, which are located at opposite sides of the display region along the second direction Y, besides the first border region 110 and the second border region 120. The second direction Y is perpendicular to the first direction X. In a case that the first border region 110 and the second border region 120 are the lower border region and an upper border region, respectively, of the display panel, the third border region 130 may be a left border region of the display panel, and the fourth border region 140 may be a right border region of the display panel. As shown in FIG. 11, the third border region and/or the fourth border region may include an anti-crack groove region 1025. Multiple grooves 1047 are provided in the anti-crack groove region to prevent a crack generated in the border region from extending into the display region. That is, the crack is prevented from affecting display performances of the display panel.

In an embodiment, the anti-crack groove region is provided in the left border region, the right border region, and the upper border region of the display panel. FIG. 11 is a cross-sectional view showing one of the left border region, the right border region, and the upper border region. In these border regions, the display panel may further include an anode layer 150 disposed between the pixel definition layer 105 and the control circuit layer 104. In one embodiment, an electric field can be formed between the anode layer 150 and the cathode layer 106 for controlling display of the display panel.

In a case that the structure as shown in FIG. 11 is of the left border region or the right border region, such part of the display panel may further includes a scanning circuit 1048 configured to provide a scanning signal for the display region of the display panel. The scanning circuit may include multiple shift registers (e.g., video shift registers, VSRs) that are cascaded.

In an embodiment, the protruding structure is disposed in the third border region, the fourth border region, or the second border region. As shown in FIG. 11, the protruding structure is located on a side of the organic-layer-free region 1021 away from the display region 101, and the material for forming the packaging layer can be effectively blocked by the protruding structure in the left border region, the right border region, or the upper border region. It is prevented that the material for forming the packaging is deposited in the electrical connection region in the left border region, the right border region, or the upper border region. Accordingly, it is prevented that the material affects performances of electrical connections in the left border region, the right border region, or the upper border region of the display panel. When viewed along a direction perpendicular to the display panel, the protruding structure 200 may or may not overlap with the anti-crack groove region 1025, which is not limited herein and may depend on an actual situation.

In another embodiment, the protruding structure is disposed in the third border region, the fourth border region, and the second border region, and the protruding structure is located at the side of the organic-layer-free region away from the display region, and the material for forming the packaging layer can be effectively blocked by the protruding structure in the left border region, the right border region, and the upper border region. It is prevented that the material for forming the packaging is deposited in the electrical connection region in the left border region, the right border region, and the upper border region. Accordingly, it is prevented that the material affects performances of electrical connections in the left border region, the right border region, and the upper border region of the display panel.

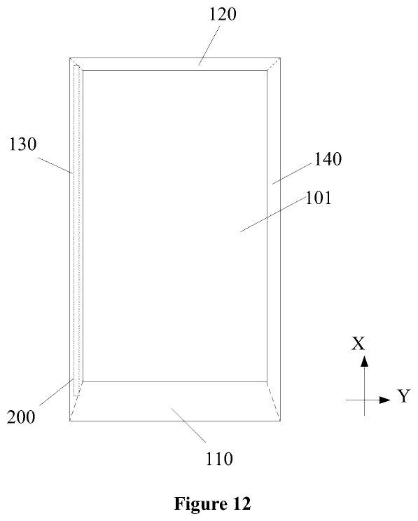

Reference is made to FIG. 12. In an embodiment, a dimension of the protruding structure 200 along the first direction X is greater than a dimension of a boundary between the display region 101 and the border region along the first direction X, and the material for forming the packaging layer which covers the display region 101 can be effectively blocked by the protruding structure 200. It is prevented that the material for forming the packaging is deposited in the left border region 130 and/or the right border region 140. Accordingly, it is prevented that the material affects performances of electrical connections in the border region of the display panel.

Reference is made to FIGS. 10 and 12. In an embodiment, an extension direction of the protruding structure 200 is parallel with the boundary between the display region 101 and the border region. The protruding structure 200 includes a continuous protruding strip. Continuity of the protruding structure 200 improves an effect of the protruding structure 200 blocking the material for forming the packaging layer and simplifies a process of fabricating the protruding structure.

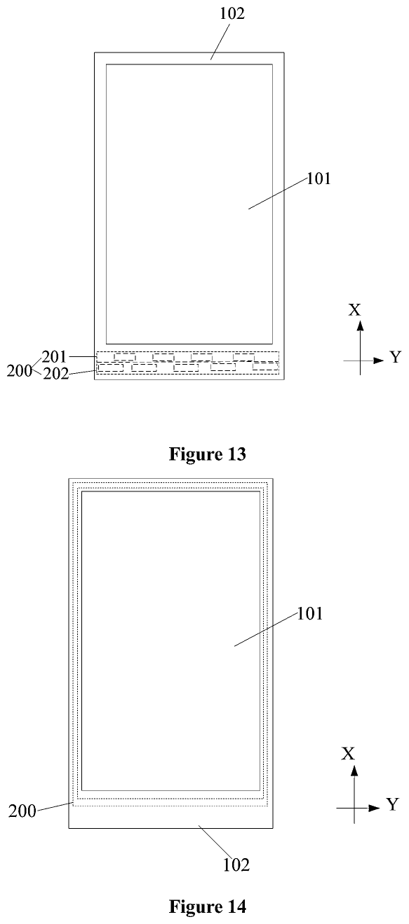

In another embodiment, the extension direction of the protruding structure is parallel with the boundary between the display region and the border region. Reference is made to FIG. 13. The protruding structure 200 may include at least two rows of protruding units, and there is a gap between every two adjacent protruding units in each row. Projections of the protruding units in the at least two rows on the boundary between the display region 101 and the border region 102 form a contiguous pattern. That is, when viewed along a direction pointing from the border region 102 to the display region 101, each row of protruding units exposes a part of the display region 101, and the at least two rows of protruding units occludes the display region 101 completely. In one embodiment, an effect of the protruding structure blocking the material for forming the packaging layer is guaranteed.

Reference is further made to FIG. 13. In an embodiment, the at least two rows of the protruding units includes a first row 201 of protruding units and a second row 202 of protruding units, and the first row 201 and the second row 202 are sequentially arranged along a direction perpendicular to the extension direction of the protruding structure and are adjacent to each other. When viewed along such direction, each protruding unit in the second row 202 overlaps with at least a part of the gap between two corresponding protruding units in the first row 201, and does not overlap with at least a part of two corresponding protruding units in the first row 201. That is, when viewed along the direction pointing from the border region 102 to the display region 101, the protruding units in the second row 202 are configured to occlude the gaps among the adjacent protruding units in the first row 201, and the protruding units in the first row 201 are configured to occlude the gaps among the adjacent protruding units in the second row 202, and the protruding units in the first row 201 and the second row 202 blocks the display region 101 completely. The effect of the protruding structure 200 blocking the material for forming the packaging layer is thus guaranteed. Specific arrangement of protruding units in the protruding structure is not limited herein. In another embodiment, the protruding structure may include three or more rows of protruding units, which depends on an actual situation.

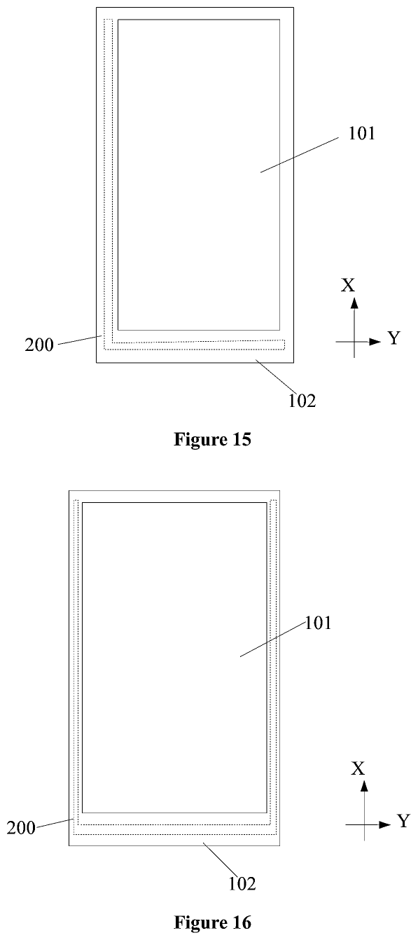

Reference is made to FIG. 14. In another embodiment, the protruding structure 200 is annular and surrounds the display region 101. In one embodiment, the material for forming the packaging layer can be blocked by the protruding structure 200 in all directions around the display region 101. It is prevented that the material is deposited on the electrical connection region in the border region and thereby affects performances of electrical connections in the border region of the display panel. A specific shape of the protruding structure 200 is not limited herein. In another embodiment, the protruding structure may be L-shaped (e.g., as shown in FIG. 15), U-shaped (e.g. shown in FIG. 16), or of another shape, which may depend on an actual situation.

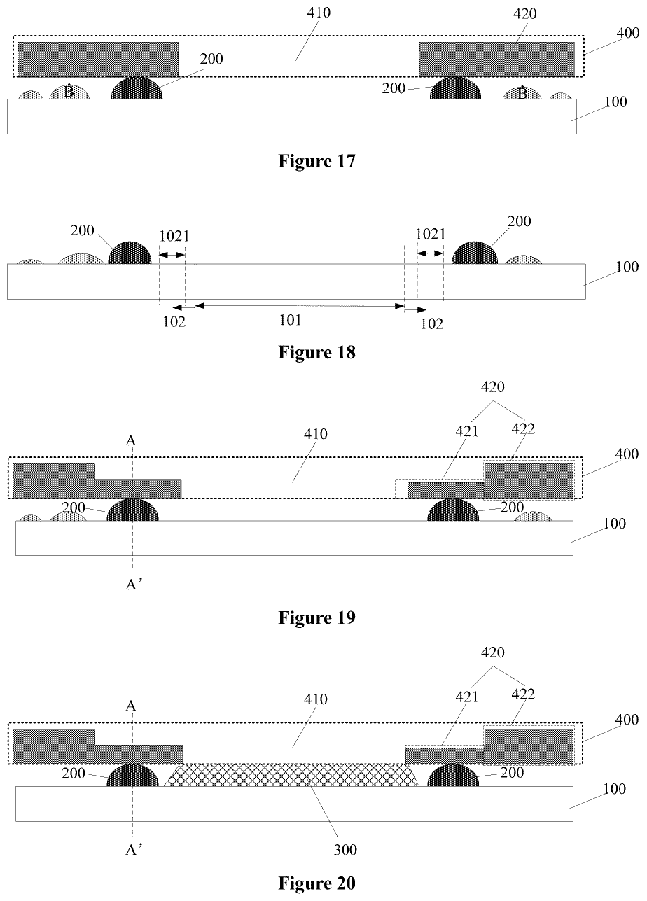

Reference is made to FIG. 17. In an embodiment, a target position B is the highest point within a first region of the array substrate 100, and the first region includes a part the border region at the side of the organic-layer-free region away from the display region. A highest point at a surface of the protruding structure 200 away from the array substrate 100 is not lower than the target position B. That is, when the mask 400 for forming the packaging layer is disposed on the array substrate 100, a position at which the mask 400 contacts the array substrate 100 is not lower than the highest point within the first region. Hence, the packaging layer can be fabricated in the whole display region, and it is less likely that the material for forming the packaging layer surpasses the protruding structure and enters the electrical connection region in the border region.

Reference is further made to FIG. 17. The highest point at the surface of the protruding structure 200 away from the array substrate 100 is higher than the target position B, and the position at which the mask 400 contacts the array substrate 100 is higher than the highest point within the first region when the mask 400 for forming the packaging layer is disposed on the array substrate 100. Hence, the packaging layer can be fabricated in the whole display region, and it is less likely that the material for forming the packaging layer surpasses the protruding structure and enters the electrical connection region in the border region.

In an embodiment, the protruding structure is insulating. Hence, the protruding structure would not affect electrical connections in the display panel, e.g., introduce a short circuit in some regions of the display panel.

In an embodiment, the protruding structure is flexible, and the mask is a steel mask of a certain mass. Hence, when the mask for fabricating the packaging layer is disposed on the protruding structure, an upper surface of the protruding structure would be pressed downward under gravity of the mask, which increases a contact area between the protruding structure and the mask and reduces a gap between the array substrate and the mask. In one embodiment, sealing performances of the contact between the protruding structure and the mask is improved, and the effect of the protruding structure blocking the material for forming the packaging layer is also improved. The present disclosure is not limited to the above cases depending on an actual situation.

In an embodiment, the protruding structure is an organic layer, which is not limited herein. In another embodiment, the protruding structure may be a flexible inorganic layer. A material of the protruding structure may depend on an actual situation. Hereinafter it is taken as an example that the protruding structure is the organic layer when illustrating the display panel.

In an embodiment, the display panel includes a thin film transistor, a pixel definition layer, a light-emitting layer, and a support structure. As shown in FIGS. 9 and 11, the display panel includes the first substrate 103, the control circuit layer 104 disposed at a side of the first substrate 103, the pixel definition layer 105 disposed at a side of the control circuit layer 104 away from the first substrate 103, a light-emitting layer, and the support structure disposed on a surface of the pixel definition layer. The control circuit layer 104 includes multiple thin film transistors, the light emitting layer is disposed in pixel definition regions of the pixel definition layer 105, and the support structure is disposed outside the pixel definition region of the pixel definition layer 105.

In an embodiment, the display panel includes multiple light-emitting regions in one-to-one correspondence to the pixel definition regions. The thin film transistors are in one-to-one correspondence to the light-emitting regions, to control light emission of the light-emitting layer in respective light-emitting regions.

In an embodiment, the protruding structure is fabricated from a same material layer (e.g., through a same process) with one or both of the pixel definition layer and the support structure. In one embodiment, the protruding structure is added into the display panel without complicating processes of manufacturing the display panel significantly. Herein the protruding structure may be fabricated from the same layer with the pixel definition layer or with the support structure. In one embodiment, the support structure may be includes two laminated layers, among which one layer is fabricated from the same layer pixel as the definition layer and the other layer is fabricated from the same layer pixel as the support structure. A specific correspondence of the layers is not limited herein.

Correspondingly, a method for manufacturing a display panel is provided according to embodiments of the present disclosure. The method includes following steps.

Reference is made to FIG. 18. An array substrate 100 and a protruding structure 200 are formed. A display region 101 of the array substrate 100 is surrounded by a border region 102 of the array substrate 100. The border region 102 includes an organic-layer-free region 1021. The protruding structure 200 is disposed in the border region 102 and at a side of the organic-layer-free region 1021 away from the display region 101.

Reference is made to FIG. 19. A mask 400 is disposed on a side of the protruding structure 200 away from the array substrate 100. At least the display region 101 is located within a projection of an opening 410 in the mask 400 on the array substrate 100. At least a projection of the protruding structure 200 on the array substrate 100 is located within a projection of a non-opening region 420 of the mask 400 on the array substrate 100. Hence, the protruding structure 200 is capable to support the mask 400 when the mask 400 is disposed on the array substrate 100. The non-opening region 420 of the mask 400 refers to a region of the mask 400 which is not the opening 410.

Reference is made to FIG. 20. A packaging layer 300 is formed through the mask 400 in the opening 410.

In an embodiment, the projection of the opening in the mask on the array substrate further covers the organic-layer-free region, which is not limited herein and may depend on an actual situation.

Reference is made to FIG. 5. In an embodiment, the packaging layer 300 includes a first inorganic layer 310, an organic layer 320, and a second inorganic layer 330, which are stacked. In an embodiment, an area of the first inorganic layer 310 and an area of the second inorganic layer 330 are both greater than an area of the organic layer 320. The first inorganic layer 310 covers at least the display region 101 and a part of the border region 102, the organic layer 320 covers at least the display region 101, and the second inorganic layer 330 covers at least the display region 101 and a part of the border region 102. Forming the packaging layer 300 within the opening 410 through the mask 400 includes at least a following step. The first inorganic layer is 310 formed within the opening through the mask 400. In another embodiment, forming the packaging layer 300 within the opening 410 through the mask 400 further includes a following step. The second inorganic layer 330 is formed within the opening through the mask 400. The present disclosure is not limited to the above steps depending on an actual situation.

In an embodiment, within a plane parallel with the array substrate, a distance from the protruding structure to the opening in the mask ranges from 0 to 60 microns. In one embodiment, the protruding structure can be disposed under the non-opening region of the mask while not challenging precision of fabricating the opening on the mask and accuracy of aligning the mask with the array substrate. A specific distance is not limited herein and may depend on specific techniques in manufacture of the display panel.

Reference is further made to FIG. 20. In an embodiment, when viewed in a direction perpendicular to the array substrate, a longitudinal centerline AA′ of the protruding structure 200 is located at a side of a boundary of the opening 410 of the mask 400 away from the display region. That is, the centerline of the protruding structure 200 overlaps with the non-opening region 420 of the mask 400. Thus, support of the protruding structure 200 on the mask 400 is stronger.

Reference is further made to FIG. 20. In an embodiment, a second region 421 of the mask 400 is located between a third region 422 of the mask 400 and the opening 410, and a thickness of the mask 400 in the second region 421 is smaller than a thickness of the mask 400 in the third region 422. In one embodiment, a probability of the material for forming the packaging layer intruding a space below the non-opening region 420 of the mask 400 is further reduced. Herein a region at which the opening is located in the mask may be called an opening region, and a region of the mask other than the opening region may be called the non-opening region.

Reference is further made to FIG. 20. In an embodiment, the projection of the protruding structure 200 on the array substrate 100 is located within a projection of the second region 421 of the mask 400 on the array substrate 100. In one embodiment, the support of the protruding structure 200 on the second region 421 of the mask 400 is stronger, and the second region 421 of the mask 400 is less likely to collapse.

In an embodiment, the mask is a steel mask. Hence, the mask has certain strength and its shape can be maintained against collapse during usage.

In an embodiment, the protruding structure is flexible. When the mask for fabricating the packaging layer is disposed on the protruding structure, an upper surface of the protruding structure may be slightly pressed downward under gravity of the mask. In one embodiment, a contact area between the protruding structure and the mask is increased, which improves sealing performances of the contact between the protruding structure and the mask. The present disclosure is not limited to the above case, which depends on an actual situation.

In an embodiment, the protruding structure is insulating. In one embodiment, the protruding structure would not affect electrical connections in the display panel, e.g., introduce a short circuit in some regions of the display panel.

In an embodiment, the protruding structure is an organic layer, which is not limited herein. In another embodiment, the protruding structure may be a flexible inorganic layer. A specific material of the protruding structure may depend on an actual situation.

In an embodiment, the display panel includes a thin film transistor, a pixel definition layer, a light-emitting layer, and a support structure. The protruding structure may be fabricated from a same layer (e.g., through a same process) as one or both of the pixel definition layer and the support structure. In one embodiment, the protruding structure is added into the display panel without complicating processes of manufacturing the display panel significantly. Herein the protruding structure may be fabricated from the same layer with the pixel definition layer or with the support structure. In one embodiment, the support structure may be includes two laminated layers, among which one layer is fabricated from the same layer pixel as the definition layer and the other layer is fabricated from the same layer pixel as the support structure. A specific correspondence of the layers is not limited herein.

A display device is further provided according to an embodiment of the present disclosure. The display device includes the display panel according to any foregoing embodiment. The display device may be an electronic device having a display function, such as a mobile phone or a tablet computer.

In summary, the display panel, the method for manufacturing the display panel, and the display device including the display panel are provided. The protruding structure is disposed in the border region of the array substrate, and the mask can be supported by the protruding structure during fabrication of the packaging layer. In one embodiment, a material for forming the packaging layer is hold at a side of the protruding structure facing the display region and is prevented from intruding into the side of the protruding structure away from the display region. It is less likely that the material of the packaging layer is deposited in the electrical connection region of the border region and thereby affects performances of electrical connection in the border region.

The embodiments of the present disclosure are described in a progressive manner, and each embodiment places emphasis on the difference from other embodiments. Therefore, one embodiment can refer to other embodiments for the same or similar parts.

According to the description of the disclosed embodiments, those skilled in the art can implement or use the present disclosure. Various modifications made to these embodiments may be made, and the general principle defined herein may be implemented in other embodiments without departing from the spirit or scope of the present disclosure. Therefore, the present disclosure is not limited to the embodiments described herein but conforms to the widest scope in accordance with principles and novel features disclosed in the present disclosure.

1. A display panel, comprising:
an array substrate, wherein a display region of the array substrate is surrounded by a border region of the array substrate, and the border region comprises an organic-layer-free region;
a protruding structure, disposed in the border region and at a side of the organic-layer-free region away from the display region; and
a packaging layer, covering the display region and at least a part of the border region, wherein the packaging layer is disposed at a side of the protruding structure facing the display region.

2. The display panel according to claim 1, further comprising:
a touch electrode layer disposed at a side of the packaging layer away from the array substrate;
wherein the array substrate further comprises a metal wiring layer, and the touch electrode layer is electrically connected to the metal wiring layer through a first via.

3. The display panel according to claim 2, wherein:
the border region comprises a first border region and a second border region which are at opposite sides of the display region along a first direction;
the first border region comprises a bendable region, and the first via is arranged in the first border region;
the protruding structure is arranged in the first border region and between the organic-layer-free region and the first via.

4. The display panel according to claim 3, wherein a dimension of the protruding structure along a second direction is greater than a dimension of the display region along the second direction, and the second direction is perpendicular to the first direction.

5. The display panel according to claim 1, wherein:
the border region comprises a third border region and a fourth border region which are at opposite sides of the display region along a second direction;
an anti-cracking groove is arranged in one or both of the third border region and the fourth border region; and
the protruding structure is arranged in the one or both of the third border region and the fourth border region and at the side of the organic-layer-free region away from the display region.

6. The display panel according to claim 5, wherein a dimension of the protruding structure along the second direction is greater than a dimension of a boundary between the display region and the border region along the second direction.

7. The display panel according to claim 1, wherein:
the protruding structure extends along a direction parallel with a boundary between the display region and the border region, and
the protruding structure comprises a continuous protruding strip.

8. The display panel according to claim 1, wherein:
the protruding structure extends along a direction parallel with a boundary between the display region and the border region; and
the protruding structure comprise at least two rows of protruding units, every two adjacent protruding units in each of the at least two rows are separated by a gap, and a projection of the at least two rows of protruding units on the boundary is contiguous.

9. The display panel according to claim 6, wherein:
the at least two rows of protruding units comprises a first row and a second row, which are sequentially arranged along a direction perpendicular to the direction parallel with the boundary; and
at least a part of each protruding unit in the second row overlaps with the gap between two corresponding protruding units in the first row when viewed along the direction perpendicular to the direction parallel with the boundary.

10. The display panel according to claim 1, wherein the protruding structure is annular and surrounds the display region.

11. The display panel according to claim 1, wherein:
a highest point of the array substrate within a first region serves as a target position, and the first region comprises a part of the border region at a side of the organic-layer-free region away from the display region; and
a highest point of a surface of the protruding structure away from the array substrate is not lower than the target position.

12. The display panel according to claim 11, wherein the highest point of the surface of the protruding structure away from the array substrate is higher than the target position.

13. The display panel according to claim 12, wherein the protruding structure is insulating and flexible.

14. The display panel according to claim 13, wherein the protruding structure is an organic layer.

15. The display panel according to claim 14, wherein:
the display panel comprises a layer of thin film transistors, a pixel definition layer, a light-emitting layer, and a support structure, and
the protruding structure is fabricated from a same layer as one or both of the pixel definition layer and the support structure.

16. A method for manufacturing a display panel, comprising:
forming an array substrate and a protruding structure, wherein a display region of the array substrate is surrounded by a border region of the array substrate, the border region comprises an organic-layer-free region, and the protruding structure is formed in the border region and at a side of the organic-layer-free region away from the display region; and
forming a packaging layer covering the display region and at least a part of the border region, wherein the packaging layer is disposed at a side of the protruding structure facing the display region.

17. The method according to claim 16, wherein forming the packaging layer comprises:
disposing a mask on a side of the protruding structure away from the array substrate, wherein at least the display region is located within a projection of an opening in the mask on the array substrate, and at least a part of a projection of the protruding structure on the array substrate is located within a projection of a non-opening region of the mask on the array substrate; and
forming a packaging layer within the opening through the mask.

18. The method according to claim 17, wherein a longitudinal centerline of the protruding structure is located at a side of a boundary of the opening of the mask away from the display region when viewed along a direction perpendicular to the display panel.

19. The method according to claim 17, wherein:
a second region of the mask is located between the opening and a third region of the mask, and the mask in the second region is smaller in thickness than the mask in the third region; and
the projection of the protruding structure on the array substrate is located within a projection of the second region on the array substrate.

20. A display device, comprising a display panel, wherein the display panel comprises:
an array substrate, wherein a display region of the array substrate is surrounded by a border region of the array substrate, and the border region comprises an organic-layer-free region;
a protruding structure, disposed in the border region and at a side of the organic-layer-free region away from the display region; and
a packaging layer, covering the display region and at least a part of the border region, wherein the packaging layer is disposed at a side of the protruding structure facing the display region.
